(19) United States
(12) Patent Application Publication
(10) Pub. No.: US 2005/0070030 A1
(43) Pub. Date: Mar. 31, 2005

(54) Device and method for forming a contact to a top electrode in ferroelectric capacitor devices

(76) Inventors: Stefan Gernhardt, Kanagawa-ken (DE); Haoren Zhuang, New York, US (US); Ulrich Egger, Kanagawa-ken (JP)

Correspondence Address: FISH & RICHARDSON, PC, 12390 EL CAMINO REAL, SAN DIEGO, CA, 92130-2081, US

(21) Appl. No.: 10/672,308

(22) Filed: Sep. 26, 2003

(51) Int. Cl. H01L 21/00

(52) U.S. Cl. 438/3

(57) ABSTRACT

A device and method for fabricating a device comprises forming a substrate and forming a contact plug through the substrate. A first electrode is formed on the substrate and a dielectric layer is formed on the first electrode. A second electrode is formed on the ferroelectric layer and an interlayer dielectric layer is applied to the second electrode and exposed surfaces of the first electrode and the ferroelectric layer. The interlayer dielectric layer is subjected to a chemical mechanical polishing process to expose a surface of the second electrode and a metal layer is deposited onto the polished interlayer dielectric layer and the exposed surface of the second electrode. The metal layer is then etched to provide an interconnection pattern to the second electrode.

### FIELD OF THE INVENTION

The present invention relates to methods and systems for forming a contact to a top electrode in, for example, ferroelectric capacitor devices.

### BACKGROUND OF THE INVENTION

A conventional ferroelectric capacitor includes a ferroelectric layer sandwiched between a bottom electrode and a top electrode. The ferroelectric layer may comprise, for example, PZT, SBT or BLT. The bottom electrode is mounted on a substrate, the electrical connection to the bottom electrode being via a metal plug through the substrate. The capacitor is covered with an interlayer dielectric hardmask, normally Tetraethyl Orthosilicate (TEOS), and connection to the top electrode is achieved by etching a window through the interlayer dielectric hardmask and filling the window with a metal filler.

A number of difficulties arise with this method of connection. Firstly, there is a danger of damage to the capacitor in the reactive ion etching process (RIE) used to create the contact window. Secondly, there is a danger of misalignment between the window and the capacitor, if the etching mask is misaligned which, given the small size of the capacitor, can easily happen. This misalignment could cause damage to the capacitor itself or could short circuit the capacitor.

One conventional way to reduce damage to the capacitor during the RIE process is to increase the thickness of the top electrode to reduce the likelihood of etching through the top electrode into the capacitor. However, this does not overcome misalignment problems.

In view of the foregoing problems with conventional processes and devices, a need exists for a method for reducing damage to the capacitor during the RIE process and for reducing alignment problems.

### SUMMARY OF THE INVENTION

In general terms, the present invention proposes that a CMP (chemical mechanical polishing) process is applied to the interlayer dielectric of a capacitor to expose the top electrode and then a metal contact to the top electrode is applied. This is considered particularly advantageous because access to the top electrode is obtained without etching the interlayer dielectric, and there is therefore minimal risk of damage being caused to the top electrode.

Also, as there is no requirement for the formation of a window to form the contact to the top electrode, the process embodying the present invention is essentially self-aligning and, unlike conventional processes, there is no danger of over-etching due to misaligned masks which could result in either damage to the ferroelectric layer or short circuiting of the capacitor.

According to a first aspect of the present invention there is provided a method for fabricating a device comprising the steps of:
forming a substrate;
forming a contact plug through said substrate;
forming a first electrode on said substrate;
forming a dielectric layer on said first electrode;
forming a second electrode on said dielectric layer;
applying an interlayer dielectric layer to said second electrode and exposed surfaces of said first electrode and/or said dielectric layer;
applying chemical mechanical polishing to said interlayer dielectric layer to expose a surface of said second electrode;
depositing a metal layer on said interlayer dielectric layer and said exposed surface of said second electrode;
etching said metal layer to provide an interconnection pattern to said second electrode.

Preferably, said exposed surface of said second electrode has a first surface area, and said metal layer has a surface having a second surface area, said surface of said metal layer contacting said exposed second electrode, and wherein the step of etching said metal layer comprises etching said metal layer such that said second surface area is greater than said first surface area. This is particularly advantageous, as when the metal layer extends over the full exposed contact area of the top (second) electrode thereby giving a complete covering of the top electrode, contact to the top electrode will be more robust and improved relative to that obtained at the bottom of a window in a conventional process.

When etching the metal layer, there may be some resist and arc ashing, however, this will be much less than during conventional processes of establishing contact to the top electrode, resulting in negligible damage to the electrode.

According to a second aspect of the present invention there is provided a device comprising;
a substrate having a contact plug extending therethrough;
a capacitor having a dielectric layer between a first electrode and a second electrode, said capacitor being mountable on said substrate;
said first electrode being formed on said substrate; and
said second electrode directly contacting an interdevice connecting metal pattern.

### BRIEF DESCRIPTION OF THE FIGURES

Preferred features of the invention will now be described, for the sake of illustration only, with reference to the following Figures in which:

FIG. 1 is a schematic cross-sectional view of an unencapsulated capacitor, that is, without the interlayer dielectric layer applied;

FIG. 2a is a schematic cross-sectional view of a prior art capacitor of the type shown in FIG. 1 with an encapsulation layer applied;

FIG. 2b is a schematic cross-sectional view of the prior art capacitor shown in FIG. 2a with connection to the top electrode established;

FIG. 3a is a schematic cross-sectional view of a capacitor according to an embodiment of the present invention with an encapsulation layer applied; and

FIG. 3b is a schematic cross-sectional view of the capacitor shown in FIG. 3a according to an embodiment of the present invention with connection to the top electrode established.

### DETAILED DESCRIPTION OF PREFERRED EMBODIMENTS

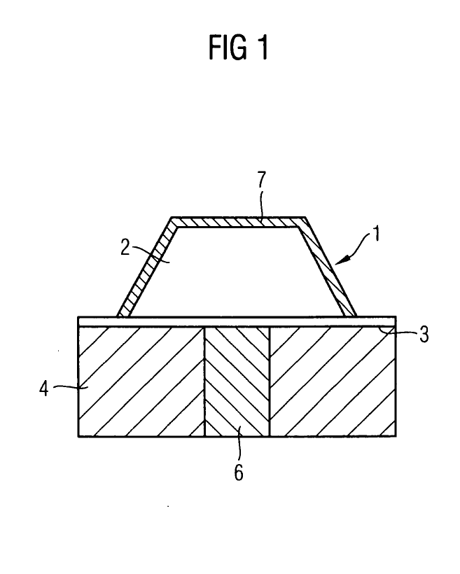

Ferroelectric capacitors 1, such as that shown in FIG. 1, consist of a ferroelectric layer 2 of material such as PZT, SBT or BLT, with electrodes above and below this layer. The bottom electrode 3 is mounted on a substrate 4, and a metal plug 6 is formed which extends through the substrate 4 to establish electrical connection to the bottom electrode 3 via the metal plug 6. The top electrode 7 lies above the ferroelectric layer 2.

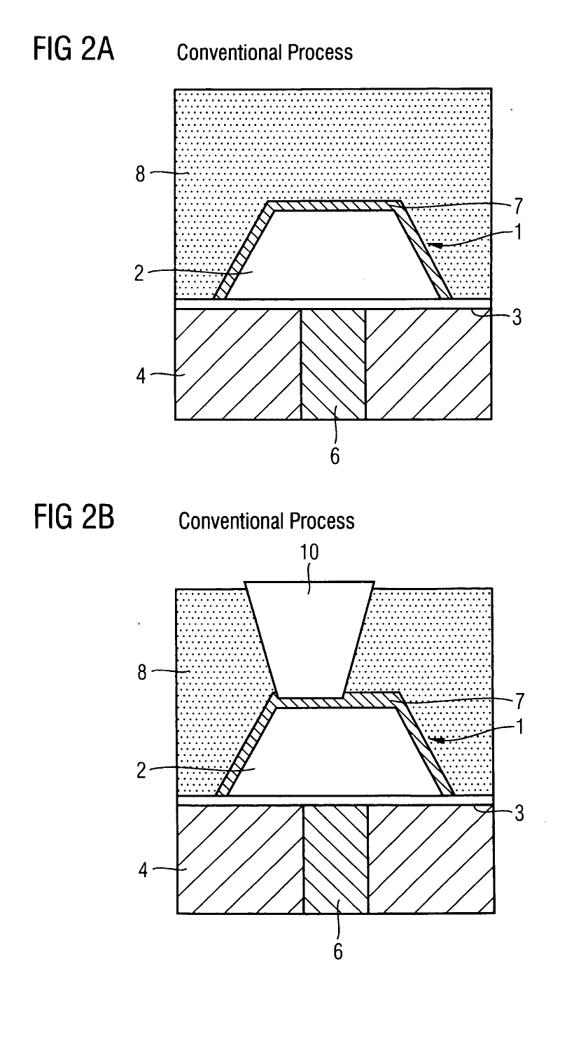

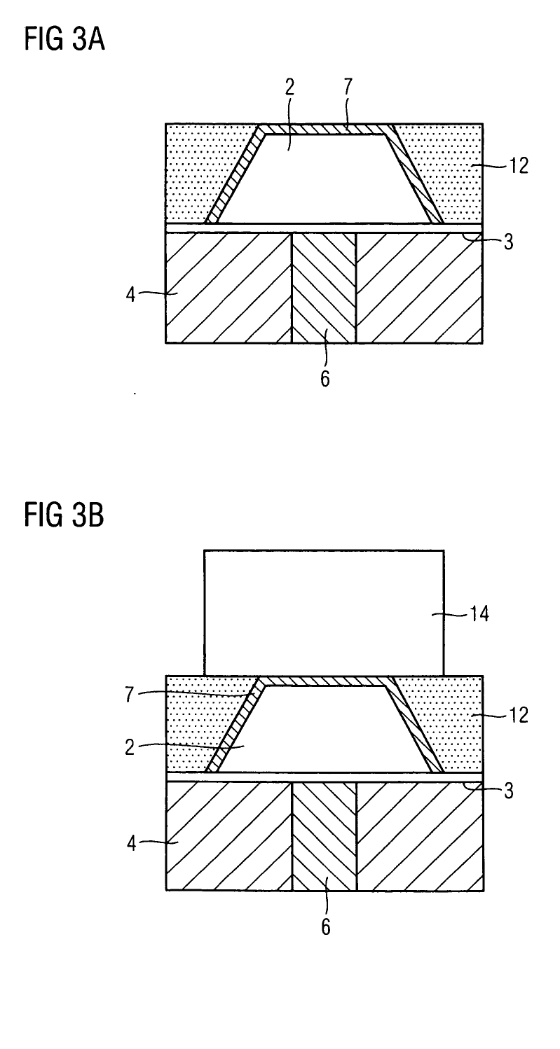

FIGS. 2a and 2b show the various processing stages of a device such as a ferroelectric capacitor 1 of the type shown in FIG. 1, according to a conventional method and FIGS. 3a and 3b show the various processing stages of a device such as a ferroelectric capacitor, according to a preferred embodiment of the present invention.

As shown in FIGS. 2a and 2b, in a conventional process for forming connection to the top electrode 7, the capacitor 1 is covered with an interlayer dielectric hardmask encapsulation 8. This interlayer encapsulation 8 may be formed in many ways, provided that it is mainly composed of insulating material. It may be of Tetraethyl Orthosilicate (TEOS) alone, but more usually is a stack of several layers, e.g. a sequence of layers of alumina, TEOS, alumina, TEOS, etc.

As shown in FIG. 2b, connection to the top electrode 7 is achieved by etching a window 10 through the interlayer dielectric 8 to the top electrode. The window 10 is then filled with a metal filler to permit establishment of electrical contact between the top electrode 7 and connections laid on the surface of the interlayer dielectric layer 8.

FIGS. 3a and 3b show the process of forming connection to the top electrode 7 according to an embodiment of the present invention. The capacitor 1 is covered with an interlayer dielectric 12. As in the capacitor of FIG. 2(a), the interlayer dielectric 12 may just be Tetraethyl Orthosilicate (TEOS) or may include a stack of several insulating different insulating materials, e.g. a sequence of layers of alumina, TEOS, alumina, and TEOS. A CMP (chemical mechanical polishing) process is applied to the surface of the dielectric 12 to remove material down to the surface of the top electrode 7, as shown in FIG. 3a thereby exposing the top electrode.

Connection to the top electrode 7 is achieved by depositing a metal layer 14 onto the exposed surface of the top electrode to establish an electrical connection. This is shown in FIG. 3b. The metal layer 14 is deposited over the capacitor and is then subjected to an RIE (reactive ion etch) process to shape the interconnection pattern of the metal layer 14. Thus, the top electrode 7 directly contacts and is directly electrically connected to an interdevice connection pattern without the requirement of etching a window to the top electrode through the interlayer dielectric layer to establish contact. Conventional processes require the formation of such a window, which is then filled with a metal filler to establish contact between the top electrode and the interdevice connecting pattern laid over the top of the interlayer dielectric layer. Thus, in conventional devices, the top electrode is spaced from the interdevice connecting pattern by the interlayer dielectric layer, the window and the filler. This is disadvantageous, as if the window be misaligned, this could result in damage to the capacitor and even the short circuiting of the capacitor. Thus, it will be seen that the present invention is particularly advantageous over conventional processes and devices.

The exposed surface area of the top electrode 7 which contacts the metal layer 14 could have a smaller surface area than that of the surface of the metal layer 14 with which it is in contact. Thus, the metal layer could extend beyond the contact face of the top electrode which makes mask alignment when etching the interconnection pattern easier.

The systems and methods according to the present invention may be particularly useful in the production of devices for use, for example, as ferroelectric random access memories.

Various modifications to the embodiments of the present invention described above may be made. For example, other materials and method steps can be added or substituted for those above. Thus, although the invention has been described above using particular embodiments, many variations are possible within the scope of the claims, as will be clear to the skilled reader, without departing from the spirit and scope of the invention.

1. A method for fabricating a device comprising the steps of:
forming a substrate;
forming a contact plug through said substrate;
forming a first electrode on said substrate;
forming a dielectric layer on said first electrode;
forming a second electrode on said dielectric layer;
applying an interlayer dielectric layer to said second electrode and exposed surfaces of said first electrode and/or said dielectric layer;
applying chemical mechanical polishing to said interlayer dielectric layer to expose a surface of said second electrode;
depositing a metal layer on said interlayer dielectric layer and said exposed surface of said second electrode;
etching said metal layer to provide an interconnection pattern to said second electrode.

2. The method according to claim 1, further comprising forming a first layer on said substrate, the step of forming said first electrode comprising forming said first electrode on said first layer.

3. The method of claim 1, wherein the step of forming a first electrode comprises connecting said first electrode to said plug through said first layer.

4. The method of claim 1, wherein said exposed surface of said second electrode has a first surface area, and said metal layer has a surface having a second surface area, said surface of said metal layer contacting said exposed second electrode, and wherein the step of etching said metal layer comprises etching said metal layer such that said second surface area is greater than said first surface area.

5. The method of claim 4, wherein said first electrode has a surface area, and the step of etching said metal layer comprises etching said metal layer such that said surface area of said metal layer is substantially equal to said surface area of said first electrode.

6. The method of claim 1, wherein the step of forming a dielectric layer on said first electrode comprises forming a ferroelectric layer on said first electrode.

7. A device comprising:
a substrate having a contact plug extending therethrough;
a capacitor having a dielectric layer between a first electrode and a second electrode, said capacitor being mountable on said substrate:
said first electrode being formed on said substrate; and
said second electrode directly contacting an interdevice connecting metal pattern.

8. A device according to claim 7 wherein said first electrode is formed on an insulating layer formed on said substrate.

9. A device according to claim 8, wherein said insulating layer is an electrically insulating layer.

10. A device according to claim 7, wherein said first electrode and said contact plug are electrically connected.

11. A device according to claim 7, wherein said dielectric layer comprises a ferroelectric layer.

12. The device of claim 7, wherein said interdevice connecting metal pattern is formed of a metal layer applied to said capacitor.

13. The device of claim 7, wherein said interdevice connecting metal pattern is etched.

14. The device of claim 12, wherein said second electrode has a first surface area contacting said interdevice connecting metal pattern, and said metal layer has a surface having a second surface area, said surface of said metal layer contacting said second electrode, and wherein said second surface area is greater than said first surface area.

15. The device of claim 12, wherein said first electrode has a surface area, and said metal layer has a surface having a second surface area, said surface of said metal layer contacting said second electrode, said surface area of said metal layer being substantially equal to said surface area of said first electrode.
